(19) United States
(12) Patent Application Publication
(10) Pub. No.: US 2019/0048458 A1
(43) Pub. Date: Feb. 14, 2019

(54) EVAPORATION SOURCE DEVICE

(71) Applicant: WUHAN CHINA STAR OPTOELECTRONICS TECHNOLOGY CO., LTD., Wuhan (CN)

(72) Inventor: Junying MU, Wuhan (CN)

(73) Assignee: WUHAN CHINA STAR OPTOELECTRONICS TECHNOLOGY CO., LTD., Wuhan (CN)

(21) Appl. No.: 15/566,711

(22) PCT Filed: Jun. 9, 2017
(86) PCT No.: PCT/CN2017/087787

§ 371 Date: Oct. 15, 2017

(30) Foreign Application Priority Data
Apr. 18, 2017 (CN) 201710252800.6

(51) Int. Cl. C23C 14/24; C23C 14/54

(52) U.S. Cl. CPC C23C 14/243; C23C 14/26; C23C 14/54

(57) ABSTRACT

An evaporation source device includes a body and a heating element. The heating element is configured to heat an evaporation material to form evaporating vapor. The body has a first chamber disposed to receive the evaporating vapor. The body includes a first wall. An outer wall surface of the first wall is configured as a curved surface curved inwardly towards the first chamber. The first wall has a slit-shaped injection port in communication with the first chamber, and the slit-shaped injection port is bent along a curvature of the first wall and is configured to guide the evaporating vapor in the first chamber outside.

### FIELD OF THE INVENTION

The present disclosure relates to the field for manufacturing liquid crystal panels, and more particularly to an evaporation source device.

### BACKGROUND OF THE INVENTION

In today's information society, the importance of display devices is more emphasized as a visual information transmission medium, but their requirements such as lighter weight, thinner profile, lower power consumption, lower cost, and higher picture quality should be satisfied in order to occupy the principal position in the future.

OLED (Organic Light Emitting Diode) display technology, compared to the current mainstream liquid crystal display technology, has the outstanding advantages of high contrast, wide color gamut, flexibility, light weight, thin profile, low power consumption, and the like. In recent years, OLED display technology has gradually become popular in areas of mobile devices, such as smart phones, tablet computers, etc., flexible wearable devices such as smart watches and the like, large size curved televisions, and white light illumination devices, etc. It has strong growth.

OLED technology mainly includes vacuum evaporation technology based small molecule OLED technology and solution process based polymer OLED technology. Evaporation machines are the current main mass equipment for manufacturing small molecule OLED components. A core part of the equipment is an evaporation source device, which is divided into a point evaporation source device, a line evaporation source device, a surface evaporation source device, etc. The line evaporation source device is currently an important mass technology mainly divided into an integrated line evaporation source device and a conveying line evaporation source device.

The current line evaporation source device is designed as a line type. The evaporation source is made to be longer than a substrate in order to ensure uniformity of the thickness of the deposition, but this results in low material utilization. Additionally, the current line evaporation source device uses round hole type injection ports to easily result in bridge material, which decreases the rate of production.

Therefore, there are defects existing in the conventional technologies which need to be improved.

### SUMMARY OF THE INVENTION

An object of the present disclosure is to provide an improved evaporation source device. To achieve the above object, the present disclosure provides an evaporation source device, including:

a body; and

a heating element configured to heat an evaporation material to form evaporating vapor, the body having a first chamber disposed to receive the evaporating vapor,

the body including a first wall, an outer wall surface of the first wall configured as a curved surface curved inwardly towards the first chamber,

the first wall having a slit-shaped injection port in communication with the first chamber, and the slit-shaped injection port bent along a curvature of the first wall and configured to guide the evaporating vapor in the first chamber outside.

In embodiments of the present disclosure, a width of the slit-shaped injection port gradually widens towards both ends of the slit-shaped injection port from an intermediate part of the slit-shaped injection port.

In embodiments of the present disclosure, the heating element is configured to control a temperature of the first chamber first increase then decrease along the curvature of the first wall.

In embodiments of the present disclosure, the heating element is configured to stepwise control a temperature of the first chamber along the curvature of the first wall.

In embodiments of the present disclosure, an inner wall surface of the first wall is configured as a curved surface curved inwardly towards the first chamber.

In embodiments of the present disclosure, the heating element is disposed in the first chamber.

In embodiments of the present disclosure, the body includes a second chamber and a second wall, the second wall has an opening part in communication with the second chamber, the body includes a third wall, the third wall includes an input opening in communication with the first chamber, and the second chamber communicates with the input opening by the opening part.

In embodiments of the present disclosure, the body further includes a gas transmission channel for communicating with the opening part and the input port.

In embodiments of the present disclosure, the heating element is disposed in the second chamber.

In embodiments of the present disclosure, the first chamber has a plurality of heating wires configured to stepwise control a temperature of the first chamber along the curvature of the first wall.

An embodiment of the present disclosure further provides another evaporation source device, including:

a body; and

a heating element configured to heat an evaporation material to form evaporating vapor, the body having a first chamber disposed to receive the evaporating vapor,

the body including a first wall, an outer wall surface of the first wall configured as a curved surface curved inwardly towards the first chamber, the heating element configured to stepwise control a temperature of the first chamber along the curvature of the first wall,

the first wall having a slit-shaped injection port in communication with the first chamber, and the slit-shaped injection port bent along a curvature of the first wall and configured to guide the evaporating vapor in the first chamber outside, wherein a width of the slit-shaped injection port gradually widens towards both ends of the slit-shaped injection port from an intermediate part of the slit-shaped injection port.

In embodiments of the present disclosure, the heating element is configured to control the temperature of the first chamber first increase then decrease along the curvature of the first wall.

In embodiments of the present disclosure, an inner wall surface of the first wall is configured as a curved surface curved inwardly towards the first chamber.

In embodiments of the present disclosure, the heating element is disposed in the first chamber.

In embodiments of the present disclosure, the body includes a second chamber and a second wall, the second wall has an opening part in communication with the second chamber, the body includes a third wall, the third wall includes an input opening in communication with the first chamber, and the second chamber communicates with the input opening by the opening part.

In embodiments of the present disclosure, the body further includes a gas transmission channel for communicating with the opening part and the input port.

In embodiments of the present disclosure, the heating element is disposed in the second chamber.

In embodiments of the present disclosure, the first chamber has a plurality of heating wires configured to stepwise control the temperature of the first chamber along the curvature of the first wall.

In embodiments of the present disclosure, the first chamber has a crucible, and the heating element is disposed in the crucible.

In embodiments of the present disclosure, a length of the slit-shaped injection port is substantially equal to a length of the outer wall of the first wall.

Compared to the existing evaporation source device, the evaporation source device of the present disclosure includes a body and a heating element. The heating element is configured to heat an evaporation material to form evaporating vapor. The body has a first chamber disposed to receive the evaporating vapor. The body includes a first wall and an outer wall surface of the first wall is configured as a curved surface curved inwardly towards the first chamber. The first wall has a slit-shaped injection port in communication with the first chamber and the slit-shaped injection port is bent along a curvature of the first wall and configured to guide the evaporating vapor in the first chamber outside. The technical solution changes an evaporating vapor flow by the curved slit-shaped injection port, which enables more evaporating vapor to be deposited in the substrate, thus increasing material utilization. Besides, the injection port is designed as the slit-shaped injection port to decrease the risk of blocking hole and thus increasing production efficiency.

For more clearly and easily understanding above content of the present disclosure, the following text will take a preferred embodiment of the present disclosure with reference to the accompanying drawings for detailed description as follows.

### DESCRIPTION OF THE DRAWINGS

The technical solution, as well as beneficial advantages, of the present disclosure will be apparent from the following detailed description of one or more embodiments of the present disclosure, with reference to the attached drawings. In the drawings:

FIG. 1 is a schematic perspective view illustrating an evaporation source device according to a preferred embodiment of the present disclosure.

FIG. 2A is a schematic front view showing the evaporation source device in FIG. 1.

FIG. 2B is a schematic top view showing the evaporation source device in FIG. 1.

FIG. 2C is another schematic top view showing the evaporation source device in FIG. 1.

FIG. 2D is a partial schematic top view showing the evaporation source device in FIG. 2C.

FIG. 2E is a schematic view of an application context showing the evaporation source device in FIG. 1.

FIG. 3 is another schematic perspective view illustrating an evaporation source device according to a preferred embodiment of the present disclosure.

FIG. 4A is an exploded schematic view showing the evaporation source device in FIG. 3.

FIG. 4B is a schematic front view showing the evaporation source device in FIG. 3.

FIG. 4C is a schematic top view showing the evaporation source device in FIG. 3.

FIG. 4D is another schematic top view showing the evaporation source device in FIG. 3.

FIG. 4E is a schematic view of an application context showing the evaporation source device in FIG. 3.

### DETAILED DESCRIPTION OF THE PREFERRED EMBODIMENTS

The embodiments described herein with reference to the accompanying drawings are explanatory, illustrative, and used to generally understand the present disclosure. Furthermore, directional terms described by the present disclosure, such as upper, lower, front, rear, left, right, inner, outer, side, etc., are only directions by referring to the accompanying drawings, and thus the used directional terms are used to describe and understand the present disclosure, but the present disclosure is not limited thereto.

In the drawings, modules with similar structures are labeled with the same reference number.

In addition, terms such as “first” and “second” are used herein for purposes of description and are not intended to indicate or imply relative importance or significance. In the description of the present disclosure, “a plurality of” relates to two or more than two. Furthermore, the terms “including” and “having” and any deformations are intended to cover non-exclusive inclusion.

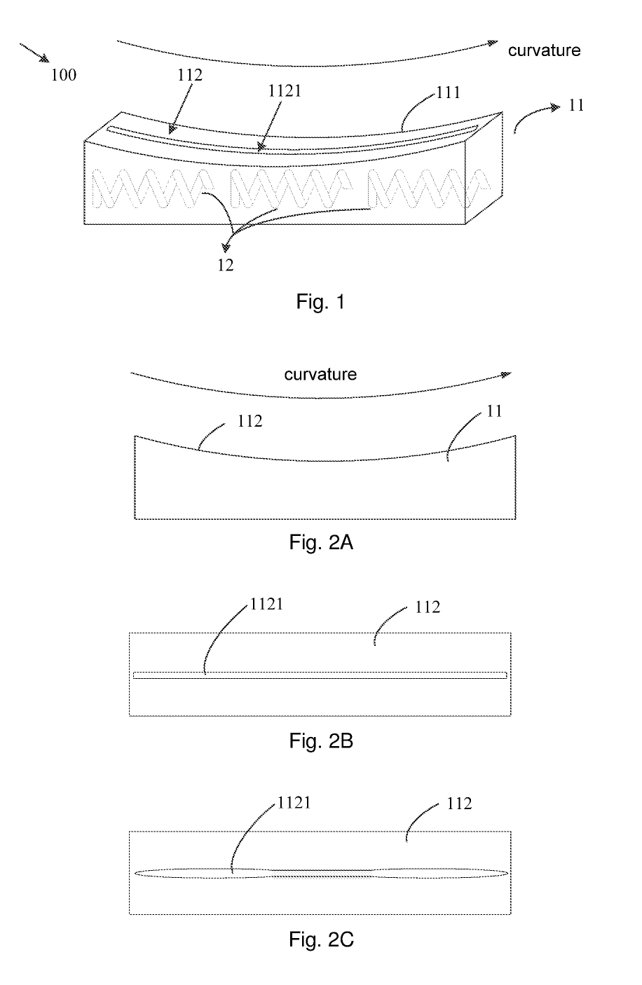

Referring now to FIG. 1, an evaporation source device according to a preferred embodiment of the present disclosure is illustrated. As shown in FIG. 1, the evaporation source device 100 of the preferred embodiment includes a body 11 and a heating element 12.

The heating element 12 is configured to heat an evaporation material to form evaporating vapor. The body 11 has a chamber 111 disposed to receive the evaporating vapor.

The body 11 includes a wall 112. An outer wall surface of the wall 112 is configured as a curved surface that is curved inwardly towards the chamber 111.

The wall 112 has a slit-shaped injection port 1121 in communication with the chamber 111. The injection port 1121 is bent along a curvature of the wall 112 and is configured to guide the evaporating vapor in the chamber 111 outside.

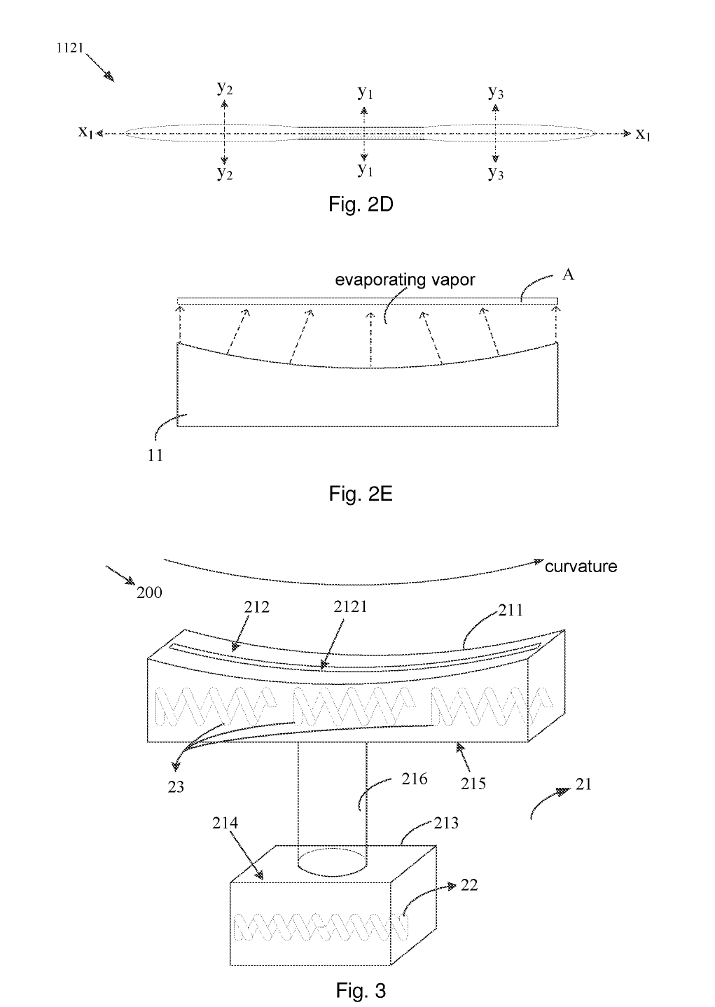

Specifically, FIG. 2A is a schematic front view showing the evaporation source device in FIG. 1. Referring to FIG. 2A, the outer wall surface of the wall 112 is gradually bent towards an intermediate part from both ends to form a camber (that is the curved surface). The curvature of the curved wall 112 can be disposed according to the actual situation.

FIG. 2E is a schematic view of an application context showing the evaporation source device in FIG. 1. Referring to FIG. 2E, the injection port 1121 is disposed on the curved wall 112, so as to change flow of an evaporating vapor and enable more evaporating vapor to concentrate towards the intermediate part and be deposited in the substrate A.

In some embodiments of the present disclosure, an inner wall surface of the wall 112 can be configured as a curved surface curved inwardly towards the chamber 111. The inner wall surface of the wall 112 can also be a flat surface. The inner wall surface of the wall 112 can also be configured as a curved surface curved towards the outer wall surface of the wall 112.

FIG. 2B is a schematic top view showing the evaporation source device in FIG. 1. Referring to FIG. 2B, the slit-shaped injection port 1121 can be a slit having a uniform width cooperating with the curvature of the wall 112.

In some embodiments of the present disclosure, the slit-shaped injection port 1121 can be a slit having a non-uniform width. Furthermore, a width of the slit-shaped injection port 1121 gradually widens towards both ends of the slit-shaped injection port 1121 from an intermediate part of the slit-shaped injection port 1121, in order to increase uniformity of the thickness of the deposition when the evaporation material is deposited on the substrate A.

FIG. 2C is another schematic top view showing the evaporation source device in FIG. 1. FIG. 2D is a partial schematic top view showing the evaporation source device in FIG. 2C. Referring to FIG. 2C, the slit-shaped injection port 1121 can be a slit having a non-uniform width. Specifically, referring to FIG. 2D, x₁-x₁ direction is a direction of the length of the injection port 1121, the width of the slit-shaped injection port 1121 gradually widens and then decreases towards both ends of the slit-shaped injection port 1121 (y₁-y₁ direction) from an intermediate part of the slit-shaped injection port 1121 (y₂-y₂ direction and y₃-y₃ direction), which enables thickness of deposition of the film on the substrate A deposited by the evaporating vapor injected from the injection port 1121 outside to be more uniform.

In some embodiments of the present disclosure, the length of the injection port 1121 is substantially equal to an arc length of the wall 112.

In some embodiments of the present disclosure, referring to FIG. 1, the heating element 12 is disposed in the chamber 111. In actual application, the chamber 111 may have a crucible and the heating element 12 can be disposed in the crucible. The heating element 12 and the evaporation material can be disposed in the crucible to form the evaporating vapor by heating.

In some embodiments of the present disclosure, the evaporation source device further includes a cooler. The cooler is disposed in the chamber 111 configured to control a temperature in the chamber 111 cooperating with the heating element 12.

Furthermore, the evaporation source device further includes a PID controlling system, configured to control the temperature in the chamber 111 precisely.

In some embodiments of the present disclosure, the heating element 12 is configured to control the temperature of the chamber 111 first to increase then to decrease along the curvature of the wall 112.

In some embodiments of the present disclosure, the heating element 12 is configured to stepwise control the temperature of the chamber 111 along the curvature of the wall 112 in order to further increase uniformity of the thickness of the deposition when the evaporation vapor is deposited on the substrate A. Referring to FIG. 1, the heating element 12 can be a plurality of heating wires disposed intervally to stepwise control the temperature of the chamber 111 along the curvature of the wall 112. For example, there is more evaporation vapor deposited towards the center of the substrate A when the width of the injection port 1121 is uniform, so as to control the temperature of the intermediate part of the heating wires to be less than the temperature of both ends of the heating wires.

Referring now to FIG. 3, another evaporation source device according to a preferred embodiment of the present disclosure is illustrated. As shown in FIG. 3, the evaporation source device 200 of the preferred embodiment includes a body 21 and a heating 22.

The heating element 22 is configured to heat an evaporation material to form evaporating vapor. The body 21 has a first chamber 211 disposed to receive the evaporating vapor.

The body 11 includes a first wall 212. An outer wall surface of the first wall 212 is configured as a curved surface curved inwardly towards the first chamber 211.

The first wall 212 has a slit-shaped injection port 2121 in communication with the first chamber 211. The injection port 2121 is bent along a curvature of the first wall 212 and is configured to guide the evaporating vapor in the first chamber 211 outside.

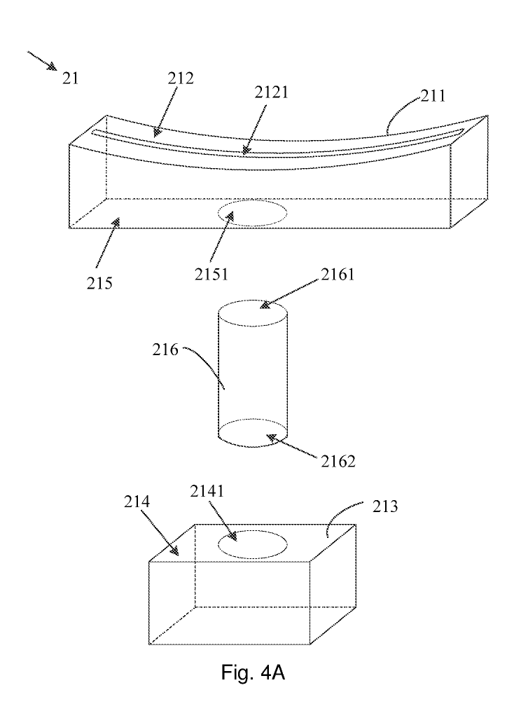

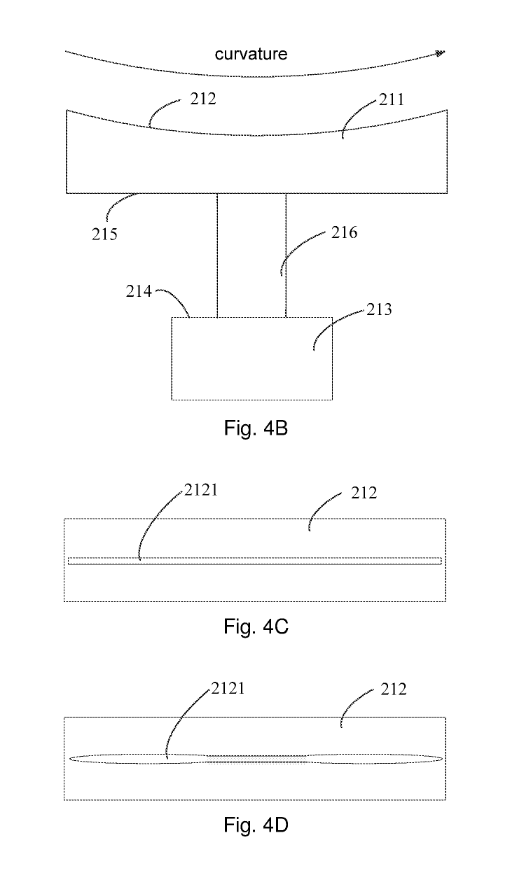

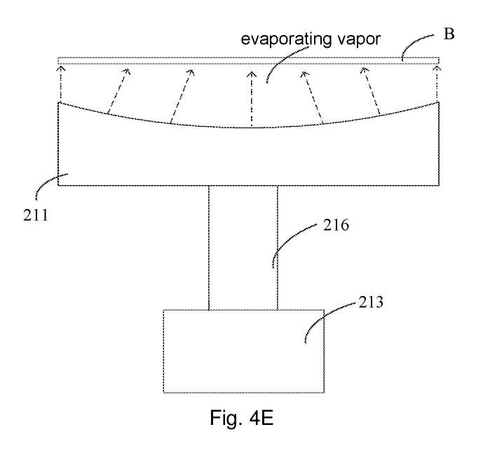

FIG. 4B is a schematic front view showing the evaporation source device in FIG. 3. Referring to FIG. 4B, the outer wall surface of the first wall 212 is gradually bent towards an intermediate part from both ends to form a camber (that is the curved surface). The curvature of the first curved wall 212 can be disposed according to the actual situation.

FIG. 4E is a schematic view of an application context showing the evaporation source device in FIG. 3. Referring to FIG. 4E, the injection port 2121 is disposed on the first curved wall 212, so as to change flow of evaporating vapor and enable more evaporating vapor to concentrate towards the intermediate part and deposit in the substrate B.

In some embodiments of the present disclosure, an inner wall surface of the first wall 212 can be configured as a curved surface curved inwardly towards the first chamber 211. The inner wall surface of the first wall 212 can also be a flat surface. The inner wall surface of the first wall 212 can also be configured as a curved surface curved towards the outer wall surface of the first wall 212.

FIG. 4C is a schematic top view showing the evaporation source device in FIG. 3. Referring to FIG. 4C, the slit-shaped injection port 2121 can be a slit having a uniform width.

In some embodiments of the present disclosure, the slit-shaped injection port 2121 can be a slit having a non-uniform width cooperating with the curvature of the first wall 212. Furthermore, a width of the slit-shaped injection port 2121 gradually widens towards both ends of the slit-shaped injection port 2121 from an intermediate part of the slit-shaped injection port 2121 in order to increase uniformity of the thickness of the deposition when the evaporation material is deposited on the substrate B.

FIG. 4D is another schematic top view showing the evaporation source device in FIG. 3. Referring to FIG. 4D, the width of the slit-shaped injection port 2121 gradually widens and then decreases towards both ends of the slit-shaped injection port 2121 from an intermediate part of the slit-shaped injection port 2121, which enables thickness of deposition of the film on the substrate B deposited by the evaporating vapor injected from the injection port 2121 outside to be more uniform.

In some embodiments of the present disclosure, the length of the injection port 2121 is substantially equal to an arc length of the first wall 212.

FIG. 4A is an exploded schematic view showing the evaporation source device in FIG. 3. Referring to FIG. 4A, the body 21 includes a second chamber 213. Specifically, the body 21 further includes a second wall 214. The second wall 214 has an opening part 2141 in communication with the second chamber 213. The body 21 further includes a third wall 215. The third wall 215 includes an input opening 2151 in communication with the first chamber 211. The second chamber 213 communicates with the input opening 2151 by the opening part 2141 to enable the first chamber 211 to be in communication with the second chamber 213.

Referring to FIGS. 3 and 4A, in embodiments of the present disclosure, the body 21 further includes a gas transmission channel 216 for communicating with the opening part 2141 and the input port 2151. Shapes of the gas transmission channel 216 may be a plurality, such as a cylindrical shape, a square tube, a core prism shape, and the like, but the present disclosure is not limited thereto.

Specifically, the gas transmission channel 216 has a first end port 2161 and a second end port 2162. The first end port 2161 communicates with the input opening 2151 of the first chamber 211. The second end port 2162 communicates with the opening part 2141 of the second chamber 213 to enable the first chamber 211 to be in communication with the second chamber 213.

In some embodiments of the present disclosure, referring to FIG. 3, the heating element 22 is disposed in the second chamber 213. In actual application, the first chamber 211 may have a crucible disposed therein. The heating element 22 and the evaporation material can be disposed in the crucible to form the evaporating vapor by heating. The heating element 22 in the second chamber 213 is configured to heat the evaporation material to form the evaporating vapor. The evaporating vapor passes through the gas transmission channel 216, is received in the first chamber 211, is injected from the injection port 2121, and then is deposited on the substrate B to form a film.

Referring to FIG. 3, in order to increase uniformity of the thickness of the deposition of the evaporation vapor deposited on the substrate B, a plurality of heating wires 23 are disposed in the first chamber 211 to stepwise control the temperature of the first chamber 211 along the curvature of the first wall 212. For example, there is more evaporation vapor deposited towards the center of the substrate B when the width of the injection port 2121 is uniform, so as to control the temperature of the intermediate part of the heating wires to be less than the temperature of both ends of the heating wires.

As described above, the evaporation source device of the embodiment of the present disclosure includes a body and a heating element. The heating element is configured to heat an evaporation material to form evaporating vapor. The body has a first chamber disposed to receive the evaporating vapor. The body includes a first wall and an outer wall surface of the first wall is configured as a curved surface curved inwardly towards the first chamber. The first wall has a slit-shaped injection port in communication with the first chamber and the slit-shaped injection port is bent along a curvature of the first wall and configured to guide the evaporating vapor in the first chamber outside. The technical solution changes an evaporating vapor flow by the curved slit-shaped injection port, which enables more evaporating vapor to be deposited on the substrate, thus increasing material utilization, improving an evaporation shadow effect, and decreasing the length of the body, so as to reduce the equipment scale and reduce costs. Besides, the injection port is designed as the slit-shaped injection port to decrease the risk of blocking and thus increasing production efficiency.

The present disclosure has been described with a preferred embodiment thereof. The preferred embodiment is not intended to limit the present disclosure, and it is understood that many changes and modifications to the described embodiment can be carried out without departing from the scope and the spirit of the invention that is intended to be limited only by the appended claims.

What is claimed is:

1. An evaporation source device, comprising:
a body; and
a heating element configured to heat an evaporation material to form evaporating vapor, the body having a first chamber to receive the evaporating vapor,
the body comprising a first wall, an outer wall surface of the first wall configured as a curved surface curved inwardly towards the first chamber, the first wall having a slit-shaped injection port in communication with the first chamber, and the slit-shaped injection port bent along a curvature of the first wall and configured to guide the evaporating vapor in the first chamber outside.

2. The evaporation source device according to claim 1, wherein a width of the slit-shaped injection port gradually widens towards both ends of the slit-shaped injection port from an intermediate part of the slit-shaped injection port.

3. The evaporation source device according to claim 2, wherein the heating element is configured to control a temperature of the first chamber first increase then decrease along the curvature of the first wall.

4. The evaporation source device according to claim 1, wherein the heating element is configured to stepwise control a temperature of the first chamber along the curvature of the first wall.

5. The evaporation source device according to claim 1, wherein an inner wall surface of the first wall is configured as a curved surface curved inwardly towards the first chamber.

6. The evaporation source device according to claim 1, wherein the heating element is disposed in the first chamber.

7. The evaporation source device according to claim 1, wherein the body comprises a second chamber and a second wall, the second wall has an opening part in communication with the second chamber, the body comprises a third wall, the third wall comprises an input opening in communication with the first chamber, and the second chamber communicates with the input opening by the opening part.

8. The evaporation source device according to claim 7, wherein the body further comprises a gas transmission channel for communicating with the opening part and the input port.

9. The evaporation source device according to claim 7, wherein the heating element is disposed in the second chamber.

10. The evaporation source device according to claim 9, wherein the first chamber has a plurality of heating wires configured to stepwise control a temperature of the first chamber along the curvature of the first wall.

11. An evaporation source device, comprising:
a body; and
a heating element configured to heat an evaporation material to form evaporating vapor, the body having a first chamber disposed to receive the evaporating vapor,
the body comprising a first wall, an outer wall surface of the first wall configured as a curved surface curved inwardly towards the first chamber, the heating element configured to stepwise control a temperature of the first chamber along the curvature of the first wall,
the first wall having a slit-shaped injection port in communication with the first chamber, and the slit-shaped injection port being bent along a curvature of the first wall and configured to guide the evaporating vapor in the first chamber outside, wherein a width of the slit-shaped injection port gradually widens towards both ends of the slit-shaped injection port from an intermediate part of the slit-shaped injection port.

12. The evaporation source device according to claim 11, wherein the heating element is configured to control the temperature of the first chamber first increase then decrease along the curvature of the first wall.

13. The evaporation source device according to claim 11, wherein an inner wall surface of the first wall is configured as a curved surface curved inwardly towards the first chamber.

14. The evaporation source device according to claim 11, wherein the heating element is disposed in the first chamber.

15. The evaporation source device according to claim 11, wherein the body comprises a second chamber and a second wall, the second wall has an opening part in communication with the second chamber, the body comprises a third wall, the third wall comprises an input opening in communication with the first chamber, and the second chamber communicates with the input opening by the opening part.

16. The evaporation source device according to claim 15, wherein the body further comprises a gas transmission channel for communicating with the opening part and the input port.

17. The evaporation source device according to claim 15, wherein the heating element is disposed in the second chamber.

18. The evaporation source device according to claim 17, wherein the first chamber has a plurality of heating wires configured to stepwise control the temperature of the first chamber along the curvature of the first wall.

19. The evaporation source device according to claim 11, wherein the first chamber has a crucible, and the heating element is disposed in the crucible.

20. The evaporation source device according to claim 11, wherein a length of the slit-shaped injection port is substantially equal to a length of the outer wall of the first wall.
